(19) United States
(12) Patent Application Publication
(10) Pub. No.: US 2009/0272461 A1
(43) Pub. Date: Nov. 5, 2009

(54) Transfer container

(76) Inventors: Daniel Alvarez, JR., San Diego, CA (US); Troy B. Scoggins, San Diego, CA (US); Russell J. Holmes, Santee, CA (US)

Correspondence Address: HAMILTON, BROOK, SMITH & REYNOLDS, P.C., 530 VIRGINIA ROAD, P.O. BOX 9133, CONCORD, MA, 01742-9133, US

(21) Appl. No.: 11/989,874

(22) PCT Filed: Jul. 31, 2006
(86) PCT No.: PCT/US06/29666

§ 371 Date: Dec. 22, 2008

Related U.S. Application Data
(60) Provisional application No. 60/714,554, filed on Aug. 3, 2005.

(51) Int. Cl. H01L 21/677; B65D 81/20

(52) U.S. Cl. 141/64; 206/710

(57) ABSTRACT

A transfer container for transferring an object between environments is described. The transfer container comprises an enclosure; a purifier comprising a purification material, the purifier attached to the enclosure, the purifier configured to purify fluid flowing into the enclosure; and a fluid propelling means, attached to the enclosure, for propelling fluid through the purifier and into the enclosure.

### RELATED APPLICATIONS

This application claims the benefit of U.S. Provisional Application No. 60/714,554 filed on Aug. 3, 2005; the contents of this application are incorporated herein by reference in their entirety.

### BACKGROUND OF THE INVENTION

The present invention relates to the purging of high purity environments to remove contamination. More specifically, the present invention provides a method for purging a standardized mechanical interface pod to ensure the quality of the environment therein. The invention particularly pertains to the purging of a container for semiconductor devices, wafers, flat panel displays, and other products requiring high purity environments while the container interfaces with a process tool or other sealed chamber.

In the fabrication of semiconductor devices the silicon wafers undergo many process steps to build the layers of material necessary for the device. Each process step requires a separate tool to perform the task and the wafers must be transported between these process tools. The reduction in feature dimensions on the wafers has driven the constantly increasing purity of the gases, chemicals, and environments that contact the wafers during each process step. Since the cleanroom environment is considerably less pure than the surface of the wafer, the exposure of the wafers to cleanroom air during transport is detrimental to the process, resulting in defects and wafer loss. The standardized mechanical interface (SMIF) system has provided a solution to the transport of wafers in the open cleanroom.

While impurity tolerance levels vary from process to process, in most process tools the advantage of point of use purification is clear. Process gases are often transported to the tool over long distances of piping throughout the fabrication facility, the greater the distance traveled the more likely that contaminants will become entrained in the stream. Furthermore, it is often not feasible for suppliers to provide gases of high enough purity to the fabrication facility. Even in cases where the production of gas of sufficient purity is practical, the likelihood of contamination during transport and installation often precludes the direct use of this gas. Therefore, many inventions exist in the prior art for the point of use purification of nearly all of the gases used in the process tools. The incorporation of these methods and devices into process tools has become standard practice in the industry.

To ensure cleanliness and for ease of transport, the wafers are typically contained within a standardized container as they travel to different process tools. The two most common types of these containers are standard mechanical interface (SMIF) pods and front opening unified pods (FOUPs). The SMIF system decreases wafer contamination by protecting the wafers from particulate contamination and providing a standardized and automated interface with the clean environment of the process tool. In the SMIF system the wafers or other sensitive devices, such as flat panel displays, are contained within the pod, which is composed of polycarbonate plastic. A typical FOUP has a capacity of 10-25 wafers, which are secured on individual shelves. The FOUP is connected to the process through an interface device or “port,” such as the Isoport® available from Asyst Technologies. The Isoport provides a kinematic coupling mechanism to align the FOUP with the tool and an automated door to open and close the FOUP for access to the wafers. Once opened, the FOUP environment comes into contact with the tool environment and the interface is generally purged by positive flow from the process tool.

Despite the purging of the interface between the FOUP and the process tool, the FOUP environment is still susceptible to impurities, both particulate and airborne molecular contaminants (AMCs), from a number of sources. The FOUP is made of a polycarbonate plastic body that is sealed to an aluminum base. The seals and resins used in the FOUP may outgas contaminants, especially contaminants absorbed during the wet rinse process in which FOUPs are cleaned. During the process step, the wafers are continuously removed from and returned to the FOUP.

Depending upon the process occurring in the tool a variety of contaminants may be retained on the surface of the wafer. As the wafers rest in the FOUP, especially if they are stored for an extended time, these contaminants may be released into the FOUP environment and contaminate additional wafers or portions of the wafer. Also, as the wafers rest in the FOUP, outside air leaks into and contaminant the FOUP environment. For reasons of safety and handling, FOUPs are not constructed to be hermetically sealed.

A separate purge specifically for the FOUP has not been incorporated into the design of Isoport stations, because experimental evidence has supported the idea that purging the FOUP is detrimental to the wafers. Veillerot, et al. (“Testing the use of purge gas in wafer storage and transport containers,” [online] 1997-2003; on the Internet at URL www.micromagazine.com/archive/03/08/verllerot.html) conducted a study in which they examined the effects of SMIF pod purging with clean dry air containing <2 ppb hydrocarbon contaminants and nitrogen containing 300 ppt hydrocarbon contaminants. Based on electrical measurements on wafers stored with and without purging, they concluded that a static environment is better than a purged container. Thus, purging of FOUPs with gas at this purity level is clearly undesirable.

In patents issued to Asyst Technologies a number of valve arrangements, sensors, and actuators have been disclosed for incorporating purge gas flow to the FOUP when it is present on the stage of the Isoport. The focus of these inventions is the introduction of purging to the Isoport without regard for control of the purge conditions. The conditions for administering purge gas are crucial to the success of the method. In addition to complications arising from gas that is not of a certain purity level, the starting and stopping of purge gas flow introduces new complications arising from the turbulent flow of gas within the FOUP. This turbulent flow, which occurs whenever gas is instantly made to flow across a pressure differential, causes particles that have settled on the bottom of the FOUP to become entrained in the stream and to subsequently settle on the surface of the wafers. As a result of purging the wafers become contaminated, resulting in defects and lost wafers. The Asyst patents clearly are a novel means to interface purge gas flow with the FOUP, but it is not practical without proper control of the purge conditions.

In U.S. Pat. No. 5,346,518 issued to IBM Corp. an elaborate system of adsorbents and filters is disclosed whereby contaminants, specifically hydrocarbons are removed from the environment within a SMIF pod. The invention involves many embodiments with alternative adsorbent arrangements to compensate for variables that might be encountered in different processes and SMIF pods. While the invention provides a novel means of protecting the FOUP environment, some major drawbacks exist when using this method. The vapor removal elements or adsorbents described in this invention rely on the diffusive transport of contaminants to them under static conditions. Therefore, the residence time of the contaminants within the FOUP may be long and certain contaminants that are irreversibly bound to the wafer surfaces will not be efficiently removed. Even if the contaminants are reversibly bound to the wafer surface, the wafer surface may still reach a quasi-steady level of contamination that is difficult to remove using a purely diffusive process. The adsorbents themselves typically rely on reversible equilibrium adsorption conditions to remove contaminants from the FOUP environment. Therefore, as contaminants become concentrated on the adsorbents they may be released into the FOUP environment. This complication is prevented by periodically replacing the adsorbents, thereby creating a new process step. Additionally, since replacement is dependant on time rather than contaminant concentration, the method is susceptible to the effects of process irregularities. For example, a system upset may result in a large amount of impure gas entering the FOUP, such as from process tool purge gas. The impurities in this gas may saturate the absorbents in the FOUP and result in their inoperability before their scheduled replacement. Since FOUPs are normally cleaned in a wet rinse process, the adsorbents must be removed or otherwise protected prior to this process. Thus, this method of contamination control possesses considerable disadvantages when compared to purging of FOUPs under the proper conditions, but the two methods are not mutually exclusive.

### SUMMARY OF THE INVENTION

One embodiment of the invention is directed to a transfer container. The container includes an enclosure, a purifier, and a fluid propelling means such as a compressor, a fan or a pressurized fluid supply. The purifier is attached to the enclosure and includes a purification material. The purifier is configured to purify fluid flowing into the enclosure. The fluid propelling means for propelling fluid through the purifier and into the enclosure, is attached to the enclosure.

In a related embodiment of the invention, the enclosure is non-hermetically sealed. In such an instance, the fluid propelling means and purifier may be configured to propel a gas having a contaminant concentration no greater than 100 parts per billion into the enclosure. In other related embodiments, the transfer container includes a front opening unified pod and/or the purification material is enclosed in a replaceable cartridge. In another related embodiment, the transfer container includes an energy source, attached to the enclosure, to drive the fluid propelling means. The energy source may be chosen to last at least 24 hours. The energy source may be a battery, a compressed gas source, a solar cell, or a fuel cell. A fuel cell may include the use of a replaceable fuel cartridge attached to the enclosure. A battery may include the use of a recharging device, for example a fan, for recharging the battery.

Another embodiment of the invention is directed to a transfer container for transferring an object. The transfer container includes an enclosure and a purifier attached to the enclosure for purifying fluid flowing into the enclosure. The purifier includes a purification material enclosed in a replaceable cartridge. The enclosure may be non-hermetically sealed. In some embodiments, the purifier may purify fluid to a contaminant concentration no greater than 100 parts per billion.

Another embodiment of the invention is directed to a transfer container having an enclosure and a purifier. The purifier is attached to the enclosure and configured as a plurality of beds. The beds are configurable so that only one bed purifies fluid flowing into the enclosure. The beds may also be configured such that only one bed purifies fluid flowing into the enclosure while at least on other bed is being regenerated. Each bed may have purification material enclosed in a removable cartridge. The enclosure may be non-hermetically sealed. At least one bed may be configured to flow fluid into the enclosure having a contaminant concentration no greater than 100 parts per billion.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a diagram illustrating process flow in a broad embodiment of the present invention.

FIG. 2 is a diagram illustrating process flow in a preferred embodiment of the present invention that incorporates feedback from a sensor.

FIG. 3A depicts a FOUP on the stage of an Isoport connected to a process tool wherein the FOUP may be purged by a method in accord with an embodiment of the present invention.

FIG. 3B depicts a SMIF pod on the stage of an Isoport connected to a process tool wherein the SMIF pod may be purged by a method in accord with an embodiment of the present invention.

FIG. 4A is an external view of a stocker, consistent with an embodiment of the invention.

FIG. 4B is a cross-sectional view of a stocker, consistent with an embodiment of the invention.

FIG. 5 is a side view schematic of a transfer container having an energy source, a fan unit, and purifier attached thereto, in accordance with embodiments of the invention.

FIG. 6 is a fluid flow diagram of a dual bed purifier system to be located on a transfer container, consistent with embodiments of the invention.

### DETAILED DESCRIPTION OF THE INVENTION

A description of preferred embodiments of the invention follows.

The use of standardized mechanical interface (SMIF) systems to control the microenvironment of sensitive devices during storage and transport within a fabrication facility has greatly improved process control and reduced device contamination. These improvements have produced higher yields of the devices and allowed for technological improvements that could not have been achieved if the devices were left in contact with the cleanroom environment. SMIF systems have played a particularly important role in the contamination control that enabled 130 nm integrated circuits and 300 mm ULSI wafers. As process improvements continue with the further implementation of these technology nodes and the drive toward future sub-micron technology nodes, contamination control becomes more crucial to the processes of semiconductor fabrication. Therefore, enhancements of the SMIF system that enable technological advancements and increase wafer yields are necessary.

Embodiments of present invention solve the problems associated with transferring objects, such that the wafers, or other contamination susceptible devices, are not contaminated between environments of SMIF pods, including front opening unified pods (FOUPs).

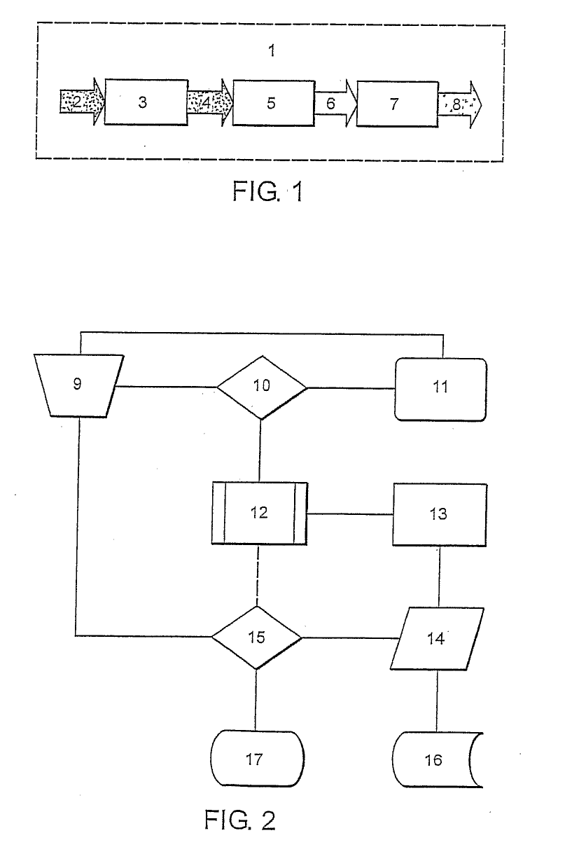

FIG. 1 illustrates the use of a SMIF. Referring to FIG. 1, purge gas 4 is made to flow through a purifier 5 such that the contaminant concentration of the purge gas 6 is ≦100 ppt total organic contamination (TOC), preferably ≦10 ppt. A flow control device 3 causes purge gas flow 2 to increase from a zero flow condition to a desired flow rate 4 at a rate such that turbulent flow and the resulting particulate entrainment are sufficiently eliminated. Purge gas is then made to flow through a SMIF pod 7 that is a part of a SMIF system 1. Thus, in its broadest embodiment the method of the present invention overcomes the major obstacles to the purging of conveyance devices for the processing of devices susceptible to very low contaminant levels, e.g. semiconductor wafers or flat panel display substrates.

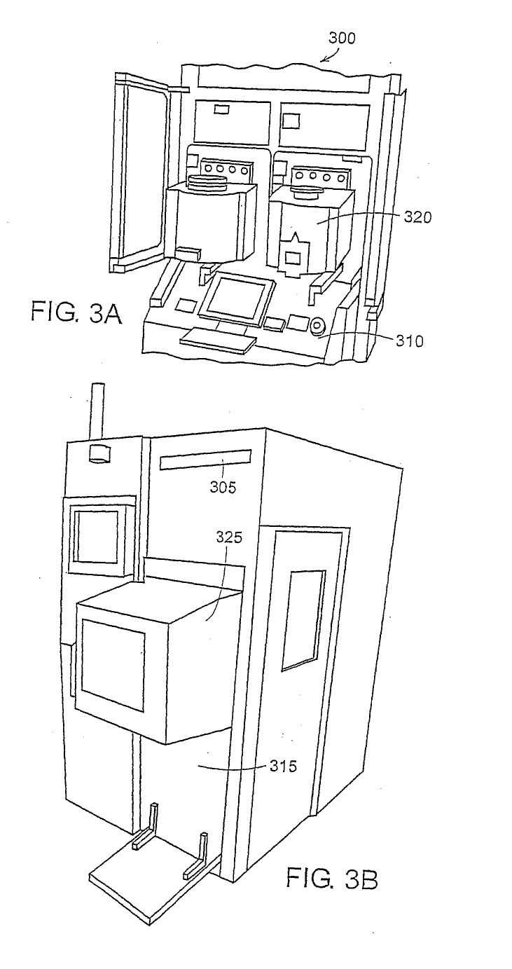

FIG. 2 depicts preferred steps of purging a SMIF pod. A SMIF pod, preferably a FOUP, is connected to a SMIF system or component thereof, preferably an Isoport or similar device or a FOUP storage rack 9. This connection involves the kinematic alignment of a multipoint contact mechanism to ensure the proper placement of the FOUP 10. If the FOUP is not properly aligned 11, an error message results and the alignment must be reattempted. If the FOUP is properly aligned, a digital signal is transmitted to a flow control device 12, the operating parameters of which have been predefined, preferably this device is a digital pressure compensating mass flow controller (MFC). The gas then flows through a purifier to ensure that its purity is within the aforementioned range 13. The pure gas exiting the purifier flows into a FOUP via a valve between the FOUP and the SMIF system. It is preferred that the opening of said valve is also controlled, either actively or passively, by the proper alignment of the FOUP, for example as in devices previously disclosed by Asyst Technologies, see U.S. Pat. No. 6,164,664 and references therein. The purge gas exits the FOUP through a valve similar to the inlet valve, and its contaminant concentration is monitored by a suitable analytical device downstream of this opening 14. When the contaminant concentration of the effluent reaches a predefined level, the analytical device transmits a digital signal to the SMIF system 15. This signal may be used by the system in a variety of manners, dependant upon the application. In some embodiments it may be stored to provide additional process control 16. In the preferred Isoport or similar device the signal results in the opening of the FOUP-process tool door by the Isoport 9. This signal may also be used by said digital MFC 12 to adjust purge gas flow through the FOUP to another predefined setpoint. Since wafers are normally continually removed from and returned to the FOUP, continuous purge gas monitoring 14 provides constant information about the environment of the nascent product. When all of the wafers have returned to the FOUP, the Isoport 9 closes the FOUP-process tool door. At this point an optional digital signal may be transmitted to the digital MFC 12 to adjust purge gas flow to a predefined setpoint. The contaminant concentration in the purge gas is again monitored 14 until it reaches an endpoint, at which time a digital signal provides notification that the FOUP is now ready for transport and/or storage 17.

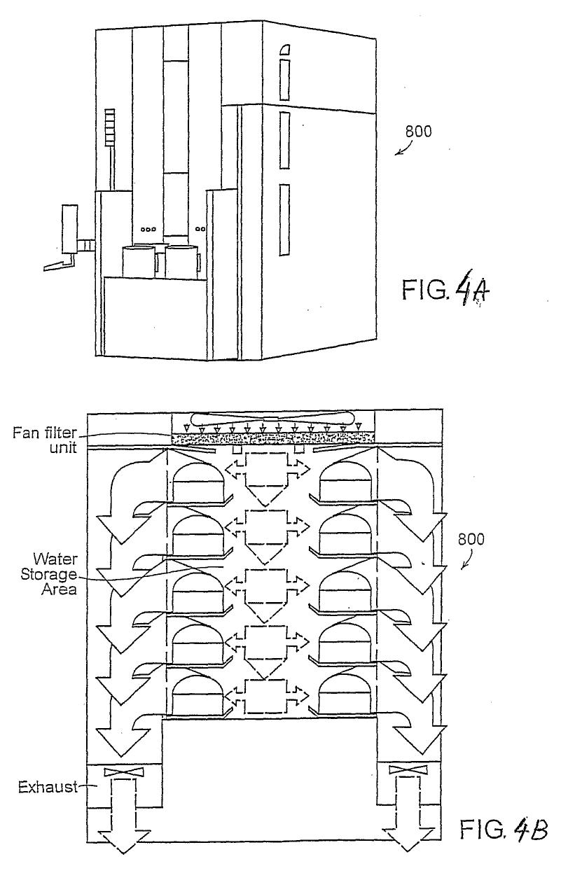

In FIG. 3A, the process tool 300 is depicted with attached load port 310, of which Isoport is one variety, with a FOUP 320 present on the stage of the load port. In an embodiment of the present invention the FOUP is purged through a port on the stage of the load port before, during, and/or after contact with the process tool has been established. According to the method, purge gas flow is introduced to FOUP with a total contaminant concentration <100 ppt, preferably <10 ppt, in a manner that sufficiently eliminates turbulent flow and the resulting particle entrainment in purge gas stream. Additionally, in FIG. 3B an alternative process tool 305 is depicted with attached load port 315 with a SMIF pod 325 present on the load port.

The present invention is not restricted to a specific purge gas. The nature of the gas used may vary according to the requirements of the manufacturing process and may be proprietary to the process or tool. Since SMIF pod purging has not been feasible prior to the present invention, the optimal purge gas may not be known to those skilled in the art. However, it is expected that the properties known to be optimal for gases used to purge similar environments will be applicable to the purging of FOUPs. Common purge gases used in other ultra high purity environments are nitrogen, argon, oxygen, air, and mixtures thereof. Recently, the applicant of the present invention has disclosed a novel purge gas found to possess considerable advantages over prior art practices for the purging of ultra high purity gas delivery lines and components. Furthermore, the use of said gas in the instant invention has been anticipated, although the methods of said use were unknown. Therefore, the preferred purge gas for use with the invention is extreme clean dry air (XCDA) as defined in U.S. patent application Ser. No. 10/683,903, U.S. Pat. No. 6,913,654, and International Application Number PCT/US2004/017251, all of which are incorporated herein by reference.

Preferably, the purge gas is purified such that the wafers, or other contamination susceptible devices, are not contaminated by said purge gas. A broad definition of this is that the purge gas is more pure than the ambient gas of the SMIF pod environment. Embodiments of the present invention are restricted to purge gases that effectively remove contaminants from the environment of the SMIF pod (e.g., purge gases with ≦100 ppt total organic contaminants, more preferably ≦10 ppt).

As previously disclosed by the applicant, the addition of certain oxygen containing species to purge gases, improves the effectiveness of a purge gas. Specifically, the addition of pure oxygen or water to oxygen-free or dry purge gases decreases the time required to reach a desired purity level of the effluent gas from a purged environment. It is speculated that the physical and chemical properties of O₂ and/or H₂O assist in the desorption of organic and other contaminants from an impure surface. Additionally, it is known to those skilled in the art that these oxygen containing species are necessary compounds in certain processes, such as the proper curing of photoresist polymers. Therefore, in certain embodiments of the present invention, water and/or oxygen may be added to the purge gas post purification. In these embodiments, the addition of these species will not result in diminished purity of the purge gas within the stated limits.

Though previously described embodiments of the invention are directed to purging wafer transfer containers such as FOUPs and other SMIF pods, it should be understood that the present invention can be practiced with more breadth. For example, the methods described by embodiments of the invention are not limited to purifying wafers and the environments of SMIF pods. The methods can be practiced with any transfer chamber that is non hermetically sealed. As well, the objects that are transferred and cleansed in the transfer container may be any semiconductor device, electronics manufacturing component, flat panel display component, or other object needing to be transferred to a purified sealed chamber (e.g., components of a high vacuum system).

One method, in accord with an embodiment of the invention, is directed to purifying a transfer container that is non hermetically sealed. The method comprises the step of purging the transfer container with a gas that has a contaminant concentration no greater than about 100 ppt.

Another embodiment of the invention is directed to a method of transferring an object from a non hermetically sealed transfer container to a sealed chamber. The method includes purging the transfer container with a gas that has a contaminant concentration no greater than about 100 ppt. Next the transfer container is exposed to the sealed chamber (e.g., by interfacing a port with a connector to allow the environments of the transfer container and sealed chamber to be in fluid communication). Finally the object is transferred between the transfer container and the sealed chamber; the object may be transferred in either direction. Optionally, the method includes the step of detecting a contaminant concentration of gas that has been purged from the transfer container. The environment of the transfer container is not exposed to the environment of the sealed chamber until the purged gas contaminant concentration is equal to or lower than a threshold concentration level.

In another embodiment of the invention, similar to the transfer method described above, the transfer container is purged with a gas. The contaminant concentration in the gas is below 2 ppb. The contaminant concentration is also low enough such that the contaminant exposure concentration in the sealed chamber, after the sealed chamber is exposed to the transfer container, is below what would be expected if the transfer container was not purged.

Another embodiment of the invention is directed to a system for transferring a semiconductor device. The system includes a non-hermetically sealed transfer container having been purged with a gas.

The concentration of the contaminant in the purge gas is preferably within the tolerances of the process and devices employed by the end user. In certain embodiments, the concentration of contaminants is no greater than 1 part per million (ppm), no greater than 10 ppm, no greater than about 20 ppm, no greater than about 30 ppm, no greater than about 40 ppm, no greater than about 50 ppm, no greater than about 60 ppm, no greater than about 70 ppm, no greater than about 80 ppm, no greater than about 90 ppm, or no greater than about 100 ppm. In other embodiments, the concentration of contaminants is no greater than 200 ppm, no greater than about 300 ppm, no greater than about 400 ppm, no greater than about 500 ppm, no greater than about 600 ppm, no greater than about 700 ppm, no greater than about 800 ppm, or no greater than about 900 ppm.

In other embodiments, the concentration of contaminants is no greater than 1 part per billion (ppb), no greater than 10 ppb, no greater than about 20 ppb, no greater than about 30 ppb, no greater than about 40 ppb, no greater than about 50 ppb, no greater than about 60 ppb, no greater than about 70 ppb, no greater than about 80 ppb, no greater than about 90 ppb, or no greater than about 100 ppb. In other embodiments, the concentration of contaminants is no greater than 200 ppb, no greater than about 300 ppb, no greater than about 400 ppb, no greater than about 500 ppb, no greater than about 600 ppb, no greater than about 700 ppb, no greater than about 800 ppb, or no greater than about 900 ppb.

In yet other embodiments, the concentration of contaminants is no greater than 1 part per trillion (ppt), no greater than 10 ppt, no greater than about 20 ppt, no greater than about 30 ppt, no greater than about 40 ppt, no greater than about 50 ppt, no greater than about 60 ppt, no greater than about 70 ppt, no greater than about 80 ppt, no greater than about 90 ppt, or no greater than about 100 ppt. In other embodiments, the concentration of contaminants is no greater than 200 ppt, no greater than about 300 ppt, no greater than about 400 ppt, no greater than about 500 ppt, no greater than about 600 ppt, no greater than about 700 ppt, no greater than about 800 ppt, or no greater than about 900 ppt.

The system also includes a sealed chamber in communication with the transfer container to allow the semiconductor device to be transferred between the sealed chamber and transfer container. Such an embodiment may also be practiced in a broadened context, wherein the object to be transferred between the transfer container and sealed chamber is not necessarily limited to a semiconductor device.

In another embodiment of the invention, a system for transferring an object between two environments comprises a transfer container and a sealed chamber. The transfer container is a non-hermetically sealed container. The transfer container is purged with a gas. The gas preferably has a concentration of contaminants within the tolerances of the process and devices employed by the end user. For example, the gas has a concentration of the contaminants no greater than about 100 parts per billion. The sealed chamber is connected with the transfer container. A closable door separates the environment of the sealed chamber from the environment of the transfer container when the door is closed. A detector is optionally included. The detector is configured to identify the contaminant concentration of the gas that is purged from the transfer container. When the contaminant concentration is equal to or below a threshold level, the detector is configured to send a signal to a controller that opens the closeable door. Subsequently, an object, such as a wafer or other semiconductor device, may be passed between the transfer container and sealed chamber.

Sealed chambers, used with the aforementioned embodiments, include chambers with an inner environment that is hermetically sealed from an exterior environment. Such chambers are constructed with walls that are gas impermeable (e.g., stainless steel). Thus, leakage of contaminants into the chamber is limited to where a port connects to another environment. Sealed chambers include semiconductor process tools (e.g., a photolithography tool) and other containment vessels, which may sustain a vacuum or other condition separate from the open atmosphere.

The use of a transfer container of the present invention is not limited to the use with FOUPs or other types of SMIF pods.

The transfer container of the present invention may be constructed with materials such as plastics (e.g., polycarbonate or polypropylene). Since the transfer container is not hermetically sealed, contaminants may leech into the environment enclosed by the transfer container. As well, when plastics are utilized, off-gassing of the plastics may further contaminate the environment in the transfer container. Another source of contamination is the object transferred by the container. For examples, wafers may off-gas and desorb a substantial amount of contaminants to the transfer container environment while the wafer is being transferred. Thus, embodiments of the invention may enable purification of the environment of such transfer chambers as well as their contents.

Contaminants to be removed from a purge gas that is used with embodiments of the invention are not limited to organics, such as hydrocarbons, but include the range of contaminants of concern in high purity processing environments. Other examples include amines, organophosphates, siloxanes, inorganic acids, and ammonia. Any of these contaminants, or mixtures thereof, may need to be removed from a purge gas. As well, such contaminants may be removed during the purge of a transfer chamber.

Gases used to purge the transfer container in the above-described embodiments include any of the gases mentioned earlier in the SMIF pod and FOUP purifying embodiments. Types of purge gases include air (e.g., XCDA), oxygen, nitrogen, water, a noble gas (e.g., argon), and mixtures of such gases.

The concentration level of contaminants in the purge gas affects the ability of embodiments of the invention to purify transfer containers sufficiently to allow exposure to a sealed chamber without detrimentally contaminating the environment of the sealed chamber. The purge gas preferably has a concentration of contaminants within the tolerances of the process and devices employed by the end user which can be any of the concentrations described above.

The flow rate of a purge gas flowing into a transfer chamber also affects the purity of environment of the transfer container, and subsequently the purity of the sealed chamber after it is exposed to the contents of the transfer chamber. Embodiments of the invention utilize a purge gas flow rate less than about 300 standard liters per minute (slm), and a gas flow rate between about 3 slm and about 200 slm in a particular embodiment.

In related embodiments of the invention, when a transfer container is purged, the flow of purge gas may be introduced in a particular manner to suppress particulate contamination in the transfer container, and subsequently in the exposed sealed chamber. The flow of purge gas is ramped from a substantially no flow condition to the desired flow rate, as opposed to being introduced in a step-wise, or substantially instantaneous fashion. This flow may be achieved by utilizing a pressure compensating mass flow controller (MFC), or a pressure controller in conjunction with a calibrated orifice for gas introduction, or any other mechanism for controlling gas flow rates in high purity chambers as understood by those of ordinary skill in the art. Such controlled introduction of the purge gas helps suppress the development of turbulent gas flow and eddys that may enhance particulate transport and thus particulate contamination in the transfer chamber.

Embodiments of the invention directed to the transfer containers described herein may or may not utilize a mass flow controller. In some instances, it is preferable to forego the expense of a mass flow controller since acceptable purging performance is still achievable.

Alternate embodiments of the invention may utilize a transfer container that holds one or more non hermetically sealed transfer containers. For example, the transfer container may be a stocker 800 than contains one or more FOUPs or other types of SMIF pods as shown in FIGS. 4A and 4B. A stocker may carry 25 FOUPs to be inserted into the environment of a tool for subsequent distribution of the FOUPs' contents into the sealed chamber. In such an instance, the flow rate of purge gas utilized in such a transfer container may range from about 100 slm to about 10,000 slm. Such embodiments may allow the contents of FOUPs to remain protected from contamination for an extended period of time relative to FOUPs that are not subject to a purged stocker. For example, components of a Cu deposition process may only be exposed to air for about 16 hours before contamination degrades such components. When placed in a FOUP nested in a stocker, about 2 days may pass before the same degradation takes place.

Some embodiments of the invention are directed to a transfer container that is configured to promote purging of the container. Because electronic fabrication facilities are heavily constrained by space and cost of equipment considerations, transfer containers that utilize purging as described herein are improved by features which decrease the size and cost of equipment necessary to enable purging. As well, specific features of transfer containers consistent with these embodiments may also allow the accrual of other advantages. Though some of these embodiments are described with specific reference to a FOUP, it should be understood that these features may also be incorporated into and/or onto other transfer containers (e.g., a SMIF pod, stocker, front opening shipping box (FOSB), isolation pods, or other containers for transporting wafers and/or electronic substrates). As well, these embodiments may or may not utilize features regarding purging conditions for transfer containers, as well as other embodiments of the invention, previously discussed herein.

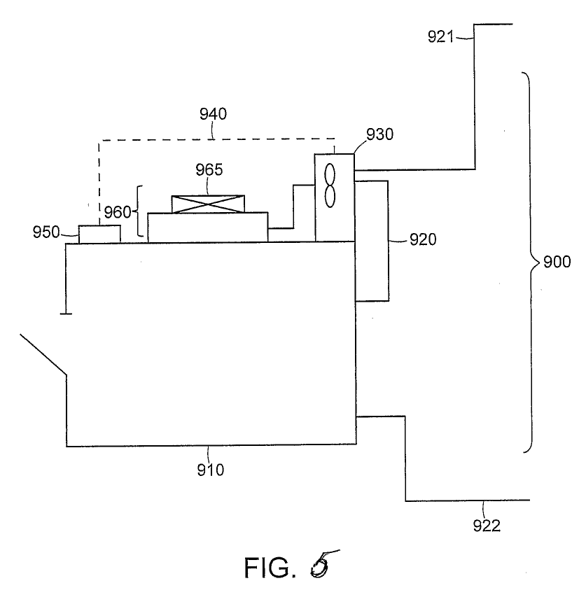

Embodiments of the invention are depicted by features shown in the schematic of FIG. 5. A transfer container 900 includes an enclosure 910 for transferring objects between environments (e.g., different tool environments of an electronics or semiconductor fab). A purifier 960 is attached to the enclosure 910 for producing a purified purge gas or fluid. In the embodiment depicted in FIG. 5, the fluid propeller is a fan unit 930 attached to the enclosure 910. In operation, the fan unit 930 propels fluid through the purifier 930 and into the enclosure 910 to purge the enclosure 910. Although the embodiment of the present invention shown in FIG. 5 employs the fan unit 930 to propel fluid, it is understood that other fluid propelling means can be used such as a compressor or a pressurized fluid supply.

The enclosure may be made of any type of material. In one embodiment, the enclosure is a non-hermetically sealed enclosure, as typically utilized in commercially available FOUPs. More tightly sealed enclosures, however, may also be utilized by some of the embodiments disclosed herein. In a particular embodiment of the invention, the enclosure is constructed with a low off-gassing or non off-gassing plastic such as perfluoroalkoxy fluorocarbon (PFA) or ultra high density polyethylene (UHDPE).

In one mode of operation, the fan unit 930 is configured to recirculate the fluid in the enclosure by drawing fluid out of the enclosure through line 920, pushing the fluid through the purifier 960, and back into the volume of the enclosure 910. Alternatively, the fan unit may draw fluid from another area (e.g., the inside of a clean room) through line 921, and push the fluid through the purifier 960 and into the volume of the enclosure 910. Fluid inside the enclosure 910 is purged out through line 922. The fan location can be altered from what is shown in FIG. 5, so long as the fan unit is able to propel the fluid through the purifier and into the enclosure 910.

In a particular embodiment of the invention, an energy source 950 is attached to the enclosure 910 for providing power to the fan unit 930 through an electrical connection 940. By including the energy source and the purifier with the transfer container, the ability to purge the transfer container is self-contained. No additional transfer conduits or external equipment, which would hinder the use of the transfer container within the context of an electronics fab, is necessary.

The energy source 950 can be any source of power compatible with the running the fan unit 930 at a sufficient rate to purge the enclosure 910 to at a desired rate, while being small enough to be portable with the transfer container (e.g., when the container is a FOUP in an electronics fab). For instance, a fan unit may draw tenths of watts of power to propel gas through the purifier and enclosure to sufficiently purge the enclosure. As well, the fan unit may need to operate for a time of at least about 24 hours, or at least about 48 hours, or at least about 72 hours in typical FOUP operation in a fab. Thus, an energy source may be configured to meet one or more of these specifications. Some types of energy sources include batteries, a solar cell, or a fuel cell. More than one type of energy source may be utilized to create the desired power output. Alternatively, energy sources can include such energy storage devices as capacitors, fly wheels, falling weights, and wound springs.

When one or more batteries are used as an energy source, the batteries may be configured to be easily replaced in a compartment or other holding device on the outside of the enclosure. Alternatively, the batteries may be rechargeable, either while installed in the energy source or by removal from the energy source before being subsequently recharged. In an alternate embodiment, the batteries are recharged using a fan unit to generate power to perform the recharging function.

The fan unit can be driven by an external source of compressed gas. The same fan unit may be used to recharge the batteries and drive gas through the purifier and enclosure, using appropriate electrical connections to achieve the dual function. Alternatively, a plurality of separate fan units may be utilized.

When a solar cell is used as an energy source, the solar cell may be embodied as a group of photovoltaic cells along one or more exterior walls of the enclosure. The solar cell may require supplementation from other energy sources to meet the power requirements of the fan unit.

When a fuel cell is used as an energy source, the fuel cell may include fuel cartridges that may be replaced upon consumption of the fuel without disturbing the contents of the enclosure of a transfer container. For example, the fuel cell may utilize a source of molecular hydrogen in a removable cartridge configuration. The hydrogen may be disposed in a pure form or diluted in a carrier to reduce the flammability danger.

In an alternative embodiment of the invention, a compressed gas source is used to purge the enclosure of a transfer container without the use of a fan unit. The source of compressed gas, either located on the transfer container or, more preferably, independent from the transfer container, is connected to a line that feeds the gas through the purifier and into the enclosure of the transfer container. A vent/outlet from the enclosure allows gas to be purged from the enclosure.

A purification material is incorporated into the purifier to remove contaminants from a fluid that subsequently purges the enclosure of a transfer container. One example of such a purification material is activated carbon fibers. In a particular embodiment, the purification material does not interact with water, i.e., the purification material does not substantially adsorb water and is not substantially degraded or deactivated by the presence of water. Thus, purge gases and fluids that contain appreciable amounts of water will not substantially reduce the working lifetime of the purification material.

Furthermore, gases that comprise water, oxygen, or water & oxygen mixtures may be especially preferred to remove contaminants within the enclosure of a transfer container, as discussed in International Application No. PCT/US2004/017251 filed Jun. 1, 2004, having International Publication No. WO2004/112117 published Dec. 23, 2004, and U.S. Pat. No. 6,913,654 issued Jul. 5, 2005; the entire contents of both documents are incorporated herein by reference. Thus various embodiments of the invention described herein may utilize a purge gas that comprises water, oxygen, or a mixture of water & oxygen, wherein the purge gas has a contamination level below about 1 part per billion on a volume basis, or preferably below about 100 parts per trillion (ppt), below about 10 ppt, or below about 1 ppt by volume. Furthermore, the purge gas may comprise between about 1% and about 25% oxygen on a volume basis, or preferably between 17% and 22% oxygen by volume. The purge gas may alternatively, or in addition, comprise more than about 100 parts per million water on a volume basis and/or less than about 2% water by volume. Also, the purge gas may comprise a sufficient amount of water, oxygen, or both components to purge contaminants, such as hydrocarbons, at a rate faster than purging with nitrogen gas.

In another particular embodiment of the invention, a transfer container includes an attached purifier 960 in which the purification material is enclosed in a replaceable cartridge 965, as depicted in FIG. 5. Thus, when the purification material requires replacement or regeneration, the material may be easily replaced without disturbing the contents of the transfer container. Furthermore, used cartridges may be analyzed to determine historical information regarding the exposure of the enclosure to contaminants. Such information may be determined using the techniques taught in International Application No. PCT/US2004/004845, filed Feb. 20, 2004, having International Publication No. WO2004/077015 published Sep. 10, 2004. The entire contents of this International Application are incorporated herein by reference. In particular, a method for analyzing contaminants in a process fluid stream includes the steps of passing an entire process fluid stream through a purifier material to thereby adsorb contaminants onto the purifier material; isolating the purifier material from the process fluid stream; desorbing the contaminants from the purifier material; and identifying the contaminants desorbed from the purifier material and determining the concentration thereof, wherein the concentration is correlated to the contaminant concentration in the entire volume of the process fluid stream.

In another embodiment of the invention, a transfer container includes a purifier for purifying fluid that flows into an enclosure of the transfer container. The purifier is configured into two or more separate beds. Each bed contains purification material capable of retaining contaminants from a gas that is passed through the bed. The beds are configured such that each bed is capable of purifying the fluid to be delivered into the enclosure, while the other beds are isolated from the enclosure and/or inlet. This allows purging of an enclosure to continue while maintenance operations are performed on the unused beds.

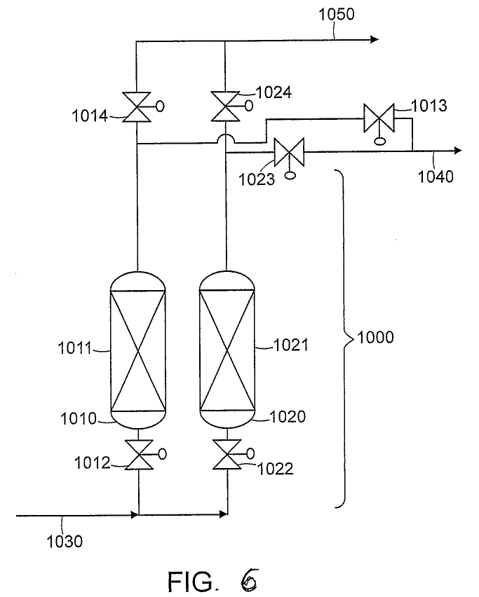

An example of the flow of purging gas, from an inlet 1030, through a purifier 1000, and out through a line 1040 to the enclosure of the transfer container, is schematically depicted in FIG. 6. Flow of gas through the two beds 1011, 1021 is controlled by valves 1012, 1013, 1014, 1022, 1023, 1024. Flow through one bed 1011 is enabled by opening the purifier's corresponding flow valves 1012, 1013, while the other bed 1021 is isolated from the enclosure and inlet by closing its corresponding valves 1022, 1023.

The dual bed configuration of a purifier mounted on a transfer container may be utilized with other embodiments of the invention disclosed herein. For example, one or more of the beds may each include a removable cartridge to easily exchange the purification material located within the bed. Such cartridges may be analyzed for historical contamination information, as described earlier.

Alternatively, one or more of the beds may each include a thermal source 1010, 1020 for thermally regenerating the bed when it is isolated and not in use. For example, with reference to FIG. 6, one bed 1011 is used to produce purging gas for the enclosure by opening valves 1012 and 1013, while valve 1014 is closed. Simultaneously, bed 1021 may be regenerated by activating a thermal source 1020. Valves 1022 and 1023 are closed such that desorbed products do not contaminate the enclosure of the transfer container. Valve 1024 is left open to vent desorbed products out line 1050.

Purifier materials that are thermally regenerable, for use with these embodiments, are preferably exposed to relatively low heating temperatures (e.g., about 200° C.) in order to activate the bed to thermally regenerate.

Other embodiments of the invention utilize a transfer container, as described herein, that further comprises an electrostatic discharger for reducing the build up of static electricity in the transfer container. Particular purging environments utilized with a transfer container (e.g., the use of extra clean dry air) can promote the build up of static charge on substrates such as wafers. Given the sensitivity of some of these substrates, an electrical discharge can result is substantial damage to the substrate. By utilizing an electrostatic discharger with the transfer container, the potential damage to materials within the transfer container is decreased. In particular, it is desirable to keep static charge build up on surfaces of the transfer container below about ±150 volts/inch, consistent with the teachings for minienvironments in the paper Integrated Minienvironment Design Best Practices (International SEMATECH; Technology Transfer #99033693A-ENG; available on the World Wide Web at URL ismi.sematech.org/docubase/document/3693aeng.pdf).

Electrostatic dischargers of any suitable type with transfer containers known to those of ordinary skill in the art may be utilized with various embodiments of the invention. In one example, a FOUP, or other transfer container, may be at least partially constructed of static dissipative or conductive materials. In general, it is desirable that portions of the transfer container that contact the carried substrates or wafers be constructed of such materials. Alternatively, other techniques for dissipating or preventing static electrical buildup may be utilized, including grounding and utilizing an ionization device within the transfer container environment.

Other related embodiments may also use the concept of static electrical discharge in other portions of the process beyond the transfer containers to maintain continuity of decreasing the risk of a discharge event.

While this invention has been particularly shown and described with references to preferred embodiments thereof, it will be understood by those skilled in the art that various changes in form and details may be made therein without departing from the scope of the invention encompassed by the appended claims.

What is claimed is:

1. A transfer container for transferring an object, comprising:
an enclosure; and
a purifier comprising a purification material, the purifier attached to the enclosure, the purifier configured to purify fluid flowing into the enclosure, the purifier further configured as a plurality of beds, the beds being configurable such that only one bed purifies fluid flowing into the enclosure.

2. The transfer container of claim 1, wherein the beds are configurable such that only one bed purifies fluid flowing into the enclosure while at least one other bed is being regenerated.

3. The transfer container of claim 1, wherein the beds are configured such that the purification material for each bed is enclosed in a removable cartridge.

4. The transfer container of claim 1, wherein the enclosure is a non-hermetically sealed enclosure, and at least one bed is configured to purify fluid flowing into the non-hermetically sealed enclosure to a contaminant concentration no greater than 100 parts per billion.

5. The transfer container of claim 1 further comprising an electrostatic discharger.

6. The transfer container of claim 1, further comprising:
a fluid propeller, attached to the enclosure, wherein said fluid propeller is a fan, a compressor, or a pressurized fluid supply, and is propelling fluid through the purifier and into the enclosure.

7. The transfer container of claim 1, wherein the fluid propeller is a fan.

8. The transfer container of claim 7, wherein the fan and purifier are configured to propel a gas into the non-hermetically sealed enclosure, the gas having a concentration of contaminants no greater than 100 parts per billion.

9. The transfer container of claim 1 further comprising:
a front opening unified pod including the enclosure.

10. The transfer container of claim 1, wherein the purification material is enclosed in a replaceable cartridge.

11. The transfer container of claim 1 further comprising:
an energy source to drive the fluid propelling means, the energy source attached to the enclosure.

12. The transfer container of claim 11, wherein the energy source includes at least one of a battery, a compressed gas source, a solar cell, and a fuel cell.

13. The transfer container of claim 12, wherein the energy source is a fuel cell, the transfer container further comprising:
a replaceable fuel cartridge attached to the enclosure.

14. The transfer container of claim 13, wherein the energy source is a battery, the transfer container further comprising:
a fan for recharging the battery, the fan driven by a source of compressed gas.

15. The transfer container of claim 11, wherein the energy source is capable of operating the fan for at least about 24 hours.
